(19) United States
(12) Patent Application Publication
(10) Pub. No.: US 2012/0123710 A1
(43) Pub. Date: May 17, 2012

(54) DEVICE AND METHOD FOR DETECTING THE ENERGY QUANTITY IN THE CHARGING STATION FOR AN ELECTRIC VEHICLE

(75) Inventors: Armn Gaul, Selm (DE); Thomas Wiedemann, Munster (DE)

(73) Assignee: RWE AG, Essen, DE (US)

(21) Appl. No.: 13/326,019

(22) Filed: Dec. 14, 2011

Related U.S. Application Data
(63) Continuation of application No. PCT/EP2010/058309, filed on Jun. 14, 2010.

(30) Foreign Application Priority Data
Jun. 22, 2009 (DE) 102009030093.7

(51) Int. Cl. G01R 21/00; G06F 19/00

(52) U.S. Cl. 702/61

(57) ABSTRACT

The present invention relates to a method and a device for detecting electrical energy delivered to an electric vehicle. To this end, the following steps are provided: connecting the electric vehicle to a charging station for obtaining electrical energy provided on a charging cable, feeding the desired energy quantity into a battery of the electric vehicle during a desired charging period, detecting of at least one electrical value required for the calculation of the energy quantity by an energy quantity meter and output of the at least one electrical value, required by the energy quantity meter for the calculation of the energy quantity, to a monitoring device for the operational monitoring of the charging station.

### CROSS-REFERENCE TO RELATED PATENT APPLICATIONS

This patent application is a continuation of PCT/EP2010/058309, filed Jun. 14, 2010, which claims priority to German Application No. 10 2009 030 093.7, filed Jun. 22, 2009, the entire teachings and disclosure of which are incorporated herein by reference thereto.

### FIELD OF THE INVENTION

The present invention relates to a method and a device for detecting electrical energy delivered to an electric vehicle.

### BACKGROUND OF THE INVENTION

So-called “electricity meters” are known for detecting delivered electrical energy quantities or electrical work. Meters of this type for consumption billing in households detect the phase current provided in the electricity network and also the applied voltage. From that they determine the watt energy quantity in the unit kilowatt-hours by means of multiplication and integration over time.

The most common are so-called “Ferraris meters” which operate in accordance with the principle of induction. Here, a magnetic rotating field is induced in an aluminium disc by the single- or multi-phase current and also the network voltage, which magnetic rotating field creates a torque in this aluminium disc by means of eddy currents. This torque is proportional to the vector product of current and voltage. The aluminium disc runs in an eddy current brake which consists of a permanent magnet, which produces a braking moment which is proportional to the speed. The aluminium disc, the edge of which is visible from the outside through a window as a cutaway, thus has a rotational speed which is proportional to the electrical real power. A drum counter is connected to the aluminium disc so that the energy throughput can be read as a numerical value in kilowatt-hours (kWh).

For tariff customers, for example in private households, electromechanical energy meters of this type with two and more counters are used in order to be able to invoice different tariffs in a time-related manner. Switching between these counters is for example carried out by means of built-in or external ripple-control receivers which are controlled by means of central ripple control systems in the energy supply company. So, the energy consumption can be billed at a lower price for the consumer in times of lower network loading, for example at night.

Digital electronic energy meters (so-called “smart meters”) which do not contain any mechanically moved elements are also known already. The current is detected by current transformers, for example with a soft-magnetic annular core or a current measurement system with Rogowski coils by means of shunt or by means of Hall elements. The calculation of the energy takes place via an electronic circuit. The result is passed to an alphanumeric display, e.g. a liquid crystal display (LCD). Digital electronic energy meters of this type have the particular advantage of remote readability and therefore make the hitherto conventional annual reading unnecessary, as the meter data are transmitted to the electricity supplier electronically, for example via the Internet.

Various variants can be used as data interfaces, e.g. infra-red, SO interface, M-bus, potential-free contact, EIB/KNX or power line carrier (PLC).

Energy quantity meters of this type are also used in charging stations for electric vehicles as separately constructed devices in order to detect and read the energy quantity fed into the battery of the vehicle. Furthermore, a charging station has a monitoring device in order to ensure its proper operation and also in order, if appropriate, to introduce appropriate protection measures in the case of an overloading of the charging station. In order to supply the monitoring device with appropriate signals, further sensors for current or power detection are usually provided within the charging station at the appropriate positions. A comparatively higher outlay in terms of measurement technology is particularly required to this end in the case of systems consisting of a plurality of charging stations.

### SUMMARY OF THE INVENTION

Starting therefrom, the invention is based on the object of developing a method or a device of the type mentioned at the beginning to the effect that a more cost-effective monitoring of the operational reliability of the charging station is given.

In the case of a method for determining the delivered energy quantity during the charging of electric vehicles, the object is achieved by means of the following features: connecting the electric vehicle to a charging station for obtaining electrical energy provided on a charging cable, feeding the desired energy quantity into the battery during a desired charging period, detecting of at least one electrical value required for the calculation of the energy quantity by an energy quantity meter, output of the calculated energy quantity, and furthermore output of at least one of the electrical values, required by the meter for the calculation of the energy quantity, to a monitoring device for the operational monitoring of the charging station.

The object is also achieved by means of a device for determining the delivered electrical energy quantity when charging electric vehicles in a charging station, with the following features: with detection means for detecting the electrical values applied in the charging circuit of an energy supply network, particularly the electric voltage and the electric current, with calculation means for calculating the energy quantity from at least one of the detected electrical values, with first output means for the calculated energy quantity, and with a further output unit for the output of the at least one further electrical value to a monitoring device for the operational monitoring of the charging station.

The invention stands out in that, in addition to the output of the energy quantity, for example to a display device or a central billing department of an energy supplier, the meter for the electrical energy quantity fed into the battery of the electric vehicle can provide the at least one further electrical value as an input signal for the monitoring device of the charging station. As this electrical value is used anyway for the calculation of the energy quantity and therefore is present in the energy quantity detection device, the outlay in terms of measurement technology for an improvement of the protective concept of the charging station can be reduced considerably, as additional components such as current transformers or measurement electronics can be dispensed with.

Preferably, it is provided that the output of the at least one electrical value necessary for the calculation of the energy quantity to the monitoring device takes place for operational monitoring of the charging station, wherein the monitoring device more preferably contains a protection device for safeguarding the phase current in the charging station. As a result, the protective concept of the charging station or for a group of charging stations can be simplified further.

According to further configurations of the invention, it is provided that the at least one electrical value required for the calculation of the energy quantity is the phase current and/or the phase voltage and/or the real power assigned to the respective phase.

The electrical value (phase current, phase voltage, phase real power) required for the monitoring device is preferably provided via a data interface, wherein this interface is either realised as a separate interface or together with the interface for the output of the calculated energy quantity.

Finally, a further aspect of the present invention also consists in the use of an energy quantity measurement device which is known per se for monitoring the operational reliability of a charging station for electric vehicles.

To this end, the device known as the “electricity meter” is merely to be modified to the effect that it provides a desired further electrical output value for the further processing in the monitoring device.

### BRIEF DESCRIPTION OF THE DRAWINGS

In the following, the subject is explained in more detail on the basis of a drawing which shows an exemplary embodiment. In the drawing:

FIG. 1 shows the schematic structure according to the exemplary embodiment;

FIG. 2 shows a detail for the energy quantity meter according to the exemplary embodiment shown in FIG. 1;

### DETAILED DESCRIPTION OF THE INVENTION

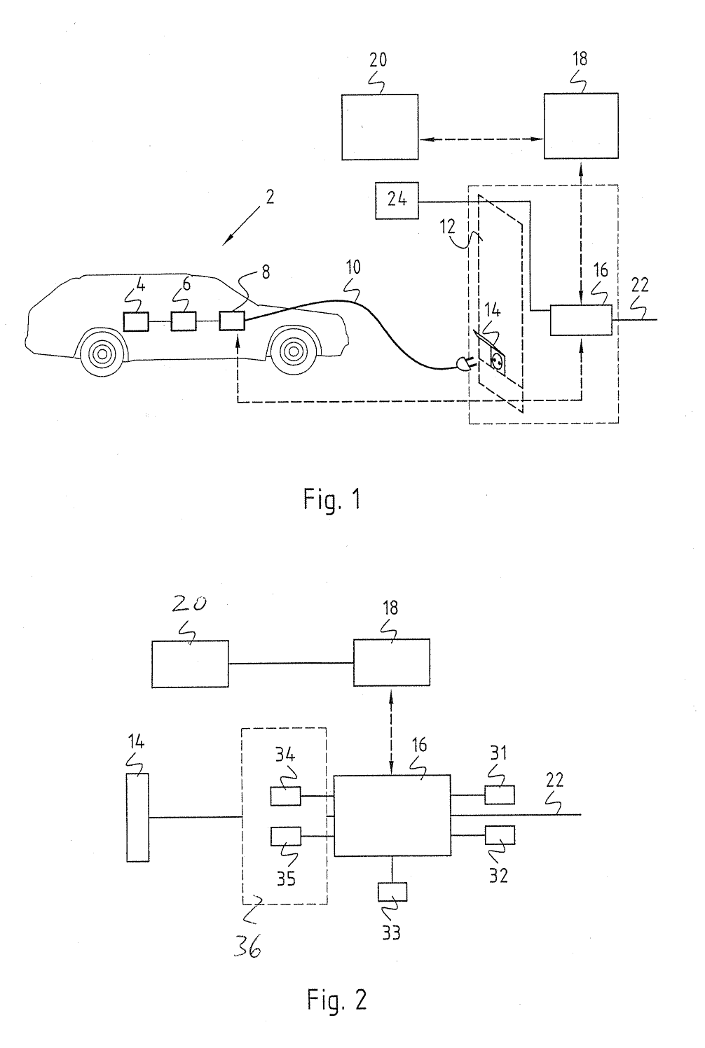

FIG. 1 shows a vehicle 2 which can be a pure electric vehicle or a hybrid vehicle. The vehicle 2 has a battery 4 and also a charge control device 6. Furthermore, the vehicle 2 has a calibrated counter 8. The battery 4 is connected to a charging station 12 via the charge control device 6 and the meter 8 by means of a cable 10. The charging station 12 has a socket 14 and also a meter 16. The meter 16 is connected to an energy supply network 22.

The FIG. 1 further shows that additional consumers 24 can be attached to the meter 16, which likewise obtain electricity from the energy supply network 22 via the meter 16.

During the charging of the vehicle 2 or the battery 4 of the vehicle 2 via the cable 10, current flows from the energy supply network 22 via the meter 16 and the socket 14 and also the cable 10, the meter 8 and the charging device 6 into the battery 4.

The meter 16 counts the energy quantity flowing into the battery 4 and also the energy quantity obtained by the consumers 24.

As can be seen from FIG. 2, on the input side, that is to say on its connection facing the energy supply network 22, the meter 16 has a first detector 31 for the phase voltage applied at this measurement point and also a second detector 32 for the phase current flowing into the meter 16. The detectors 31, 32 are constructed as conventional detectors for the corresponding electrical values, that is to say e.g. as ring-core current transformers, Hall sensors, etc. The energy quantity delivered over a certain period of time is calculated from the output signals of the detectors 31, 32 and this can be displayed on a display device 33 of the meter 16.

The meter 16 is a remote reading meter which is connected to a billing centre 20 via a communication network 18. The communication network 18 can be part of the energy supply network 22, so that a communication can for example take place via the energy supply network 22 by means of power line communication. The communication network 18 can also be a wired or wireless communication network. An IP protocol can for example be used for communication.

On the output side, the meter 16 has not only a display device 34 for the calculated energy quantity, but also a further output unit 35 for the phase current which is detected via the detector 32. The further output unit 35 can output the measured value of the detector 32 directly or a further processed signal derived therefrom. Alternatively thereto, the phase voltage or a correspondingly further processed signal of the detector 31 can also be output by the further output unit 35. Finally, the output by the further output unit 35 of an output signal derived in common from the signals of the detectors 31 and 32, particularly the phase real power, is also conceivable.

A data interface 36 for the measured energy quantity is assigned to the further output unit 35 as well as to the output unit 34, wherein this data interface can be constructed separately or together (as shown in FIG. 2) with the data interface for the energy quantity.

The phase current or another electrical signal is available via the data interface 36 for further processing. The further processing takes place in a monitoring device which has the purpose of ensuring the operational reliability of the respective charging station. This further functionality is given without additional outlay for the detectors of the phase currents being necessary to this end. Namely, it is possible to dispense with additional current transformers and the associated measurement technology components, because these are already present in the meter 16.

For a system consisting of a plurality of charging stations, the respective phase currents in the individual stations can be monitored separately in this manner and in this manner a common protective concept can be built up without additional outlay for the detectors or the signal detection and conditioning being necessary.

In this case, the monitoring device can be connected to a protection device, by means of which the charging station is safeguarded with respect to a possible overloading. To this end, measured values for the respective phase current are transmitted from the meter 16 within predetermined time sections to the protection device via the data interface 36 and appropriate protection functions of the charging station are activated in the event of reaching a critical trigger value.

Alternatively, or in addition to the output of the phase current, the output of a measured value can take place for the current real power in the related phase. This measured value also can be transmitted via a separate or common data interface for further processing and form an input value for the monitoring device and/or the protection device of the charging station.

What is claimed is:

1. A method for determining a delivered energy quantity during the charging of electric vehicles, comprising:
connecting an electric vehicle to a charging station for obtaining electrical energy provided on a charging cable;
feeding the desired energy quantity into a battery of the electric vehicle during a desired charging period;
detecting of at least one electrical value required for the calculation of the energy quantity by an energy quantity meter;
output of the calculated energy quantity; and
output of the at least one electrical value, required by the energy quantity meter for the calculation of the energy quantity, to a monitoring device for the operational monitoring of the charging station.

2. The method according to claim 1, wherein the output of the at least one electrical value, required for the calculation of the energy quantity, to a monitoring device takes place for conduction current monitoring of the charging station.

3. A device for determining a delivered electrical energy quantity when charging electric vehicles in a charging station, comprising:
a detection means for detecting the electrical values applied in the charging circuit of an energy supply network, particularly the electric voltage and the electric current;
a calculation means for calculating the energy quantity from at least one of the detected electrical values;
a first output unit for the calculated energy quantity; and
a further output unit for the output of at least one further electrical value to a monitoring device for operational monitoring of the charging station.

4. The device according to claim 3, wherein the at least one electrical value required for the calculation of the energy quantity is the phase current.

5. The device according to claim 3, wherein the at least one electrical value required for the calculation of the energy quantity is the phase voltage.

6. The device according to claim 3, wherein the at least one electrical value required for the calculation of the energy quantity is the real power assigned to the respective phase.

7. The device according to claim 3, wherein the monitoring device contains a protection device, particularly for safeguarding the phase current.

8. The device according to claim 3, wherein the further output unit is constructed to output the at least one further electrical value to the monitoring device via a data interface.

9. The device according to claim 8, wherein the data interface is constructed together with an interface unit for the first output means for the calculated energy quantity.
